(19) United States
(12) Patent Application Publication
(10) Pub. No.: US 2023/0245894 A1
(43) Pub. Date: Aug. 3, 2023

(54) PROCESS FOR SELECTIVELY DEPOSITING HIGHLY-CONDUCTIVE METAL FILMS

(71) Applicant: ENTEGRIS, INC., Billerica, MA (US)

(72) Inventors: Philip S.H. Chen, Bethel, CT (US); Bryan Clark Hendrix, Danbury, CT (US); Thomas M. Cameron, Newtown, CT (US)

(21) Appl. No.: 18/102,641

(22) Filed: Jan. 27, 2023

Related U.S. Application Data
(60) Provisional application No. 63/306,287, filed on Feb. 3, 2022.

(51) Int. Cl. H01L 21/285; C23C 16/14

(52) U.S. Cl. CPC H01L 21/28568; C23C 16/14; H01L 21/76876

(57) ABSTRACT

Provided is a process comprising a selective ruthenium seed layer deposition with oxygen-free ruthenium precursors, followed by bulk deposition of metal-containing precursors such as tungsten, molybdenum, cobalt, ruthenium, and/or copper-containing precursors. The ruthenium seed layer deposition is highly selective for the conducting portions of the microelectronic device substrate while minimizing deposition onto the insulating surfaces of the microelectronic device substrate. In certain embodiments, the conducting portions of the substrate is chosen from titanium nitride, tungsten nitride, tantalum nitride, tungsten, cobalt, molybdenum, aluminum, and copper.

### PRIORITY CLAIM

The invention claims priority to U.S. provisional patent No. 63/306,287 with a filing date of Feb. 3, 2022, which is incorporated by reference herein.

### TECHNICAL FIELD

The invention relates generally to the field of vapor deposition. In particular, the invention relates to the selective deposition of ruthenium-containing precursors followed by bulk deposition of various metals onto microelectronic device substrates.

### BACKGROUND

In the fabrication of microelectronic devices, tungsten is generally deposited on a titanium nitride barrier. The process involves a nucleation layer deposition using tungsten hexafluoride and a silicon or boron source followed by bulk deposition using tungsten hexafluoride and hydrogen, as a reducing gas. Unfortunately, the material in such a nucleation layer is often very fine-grained and exhibits high resistivity. Additionally, this nucleation step is non-selective and so side walls of the device tend to also be covered with this high resistivity metal.

In the deposition of molybdenum-containing films onto microelectronic device substrates, molybdenum pentachloride and molybdenum oxytetrachloride have been developed for chemical vapor deposition of high purity and low resistivity molybdenum metal. However, molybdenum also generally requires similar non-selective pulsed nucleation techniques to deposit onto titanium nitride surfaces at temperatures less than about 500° C.

Thus, a need remains for the ability to deposit low resistivity nucleation (i.e., seed) layers onto metallic surfaces such as titanium nitride, with high selectivity to surrounding dielectrics and thus enabling the bulk deposition of materials such as a tungsten, molybdenum, cobalt, ruthenium, or copper metal-containing films

For the scaling of integrated semiconductor devices, the resistance of the conductive vias that connect layers of wiring has become a significant portion of the overall resistance-capacitance (RC) delay in communication within the integrated device. In order to minimize the via resistance, the volume consumed by higher resistivity barriers, adhesion layers, and nucleation layers needs to be minimized. One of the ways to fill the entire volume of a via with low resistivity metal is to nucleate and grow from the metal contact at the bottom of the via to the top without growing in from the dielectric sidewalls of the via. Accordingly, a need exists for selective deposition on such metal contacts.

### SUMMARY

In summary, the invention provides a process comprising a selective ruthenium seed layer deposition with oxygen-free ruthenium precursors, followed by bulk deposition of metal-containing precursors such as tungsten, molybdenum, cobalt, ruthenium, and/or copper-containing precursors. The ruthenium seed layer deposition is highly selective for the conducting portions of the microelectronic device substrate while minimizing deposition onto the insulating surfaces of the microelectronic device substrate. In certain embodiments, the conducting portions of the substrate is chosen from titanium nitride, tungsten nitride, tantalum nitride (all conducting nitrides), tungsten, cobalt, molybdenum, aluminum, and copper (metal 1 in FIG. 6). In certain embodiments, the insulating surfaces are chosen from silicon oxide, silicon nitride, and other dielectrics, as well as low k dielectrics.

The ruthenium seed layers exhibited an as-deposited electrical resistivity of about 450 μΩ-cm for a 5.3 Å thick ruthenium film from a p-cymene cyclohexadiene precursor on a titanium nitride substrate at 300° C. This process was also highly selective as shown by only about 0.3 Å of ruthenium deposited onto an adjoining silicon oxide surface, thus presenting a selectivity for the conducting portion of the substrate over the insulating portion of the substrate. This highly conductive seed layer enables the bulk deposition of the metals recited above.

### BRIEF DESCRIPTION OF THE DRAWINGS

FIG. 1 is a graph illustrating the self-limiting deposition and deposition selectivity for titanium nitride over SiO₂ as set forth in Example 1. This deposition selectivity was demonstrated at 94% at 5 angstroms of ruthenium.

FIG. 2 is a graph showing as-deposited resistivity for the ruthenium film on titanium nitride at various thicknesses.

FIG. 3 is a scanning electron micrograph (SEM) top-down image of a 5.3 Å thick ruthenium layer deposited on a titanium nitride substrate. (10 Minutes, 446.1 PQ-cm)

FIG. 4 is a graph demonstrating self-limiting deposition and selectivity for titanium nitride over silicon dioxide, for the deposition of ethylbenzyl(1-ethyl-1,4-cyclohexadienyl)Ru with H₂ as co-reactant, as set forth in Example 2.

FIG. 5 is a graph showing as-deposited resistivity for ruthenium on titanium dioxide and silicon dioxide, at various thicknesses as per Example 2.

FIG. 6a is an illustration of the problem posed in the art where non-selective deposition often results in a void space the in the filling of the via with “Metal 2” as depicted.

FIG. 6b is an illustration of the solution to this problem believed to be enabled by the process of the invention, i.e., a via structure without such a void space. FIG. 6c is thus an illustration of the selective deposition of Metal 2 onto “Metal 1” in a highly selective fashion, thus enabling a bottom-up filling of the via with Metal 2.

### DETAILED DESCRIPTION

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The term “about” generally refers to a range of numbers that is considered equivalent to the recited value (e.g., having the same function or result). In many instances, the term “about” may include numbers that are rounded to the nearest significant figure.

Numerical ranges expressed using endpoints include all numbers subsumed within that range (e.g., 1 to 5 includes 1, 1.5, 2, 2.75, 3, 3.80, 4 and 5).

In a first aspect, the invention provides a process for depositing a metal-containing film onto a microelectronic device substrate, wherein the metal is chosen from tungsten, molybdenum, cobalt, ruthenium, and copper, and wherein the substrate is chosen from titanium nitride, tungsten nitride, tantalum nitride, niobium nitride, tungsten, molybdenum, cobalt, and copper which comprises:
a. introducing an oxygen-free ruthenium precursor material into a reaction zone containing the substrate, in the presence of a reducing gas, under vapor deposition conditions, until the ruthenium-containing film is about 3 to about 15 Å in thickness, followed by
b. introducing a tungsten, molybdenum, cobalt, ruthenium, or copper metal-containing precursor into the reaction zone, under vapor deposition conditions, until a tungsten, molybdenum, cobalt, ruthenium, or copper metal-containing film of a desired thickness has been obtained.

The process of the invention enables the bulk deposition of certain metal-containing films onto a substrate which has been provided with a highly-conductive ruthenium seed layer (step a). This selectively-formed and highly-conductive ruthenium layer may be deposited using methodology described in U.S. Patent Publications 2020/0149155 and 2020/0157680, incorporated herein by reference. As noted, in this step a., an oxygen-free ruthenium precursor material is utilized. In one embodiment, this oxygen-free ruthenium precursor is chosen from:

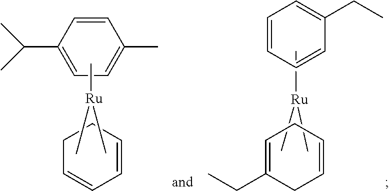

referred to herein as “p-cymene CHD Ru” and “EBECHD Ru”, respectively.

Once the ruthenium seed layer, having a thickness of about 3 to about 15 Å has been formed, step b. is utilized to introduce a tungsten, molybdenum, cobalt, ruthenium, or copper metal-containing precursor. In this regard, the ruthenium precursor utilized in step b can be an oxygen-free ruthenium precursor or an oxygen-containing ruthenium precursor, in either event, chosen from known ruthenium precursor materials. In the event the ruthenium precursor contains oxygen, it may be desirable to utilize a reducing gas as co-reactant in order to properly deposit the desired metal (i.e., in the zero-oxidation state). Exemplary reducing gases include hydrogen, ammonia, hydrazine, methyl hydrazine, t-butyl hydrazine, 1,2-dimethyl hydrazine, and 1,1-dimethyl hydrazine.

In certain embodiments, vapor deposition conditions comprise reaction conditions known as chemical vapor deposition, pulsed-chemical vapor deposition, and atomic layer deposition. In the case of pulsed-chemical vapor deposition, a series of alternating pulses of the precursor composition and co-reactant(s), either with or without an intermediate (inert gas) purge step, can be utilized to build up the film thickness to a desired endpoint.

In certain embodiments, the pulse time (i.e., duration of precursor exposure to the substrate) for the precursor compounds depicted above ranges between about 1 and 30 seconds. When a purge step is utilized, the duration is from about 1 to 20 seconds or 1 to 30 seconds. In other embodiments, the pulse time for the co-reactant ranges from 5 to 60 seconds.

In one embodiment, the vapor deposition conditions for step a, i.e., the deposition of the ruthenium seed layer, comprise a temperature in the reaction zone of about 100° C. to about 400° C., or about 200° C. to about 350° C., and at a pressure of about 1 Torr to about 100 Torr.

The step b. bulk deposition of a metal film depends on the particular metal precursor chosen and will involve a variety of temperatures, pressures, and co-reactant gases.

For example, in the case of molybdenum hexacarbonyl and tungsten carbonyl, U.S. Patent Publication No. 2021/0062331, incorporated herein by reference, describes temperatures of about 250° C. to about 750° C.

U.S. Patent Publication No. 2020/0199743 describes temperatures of less than about 480° C. and pressures of less than about 100 Torr for precursors such as MoCl₅, MoOCl₄, MoO₂Cl₂, WCl₆, WCl₅, WOCl₄, and WO₂Cl₃.

For the various ruthenium precursors, the vapor deposition temperatures are generally about 100° C. to about 500° C., and pressures are generally about 10 mTorr to about 30 Torr.

For the various cobalt precursors, the vapor deposition temperatures are generally about 70° C. to about 480° C., and pressures are generally about 0.2 Torr to about 760 Torr.

For the various copper precursors, the vapor deposition temperatures are generally about 40° C. to about 200° C., and pressures are generally about 0.2 to about 30 Torr.

In one embodiment, the ruthenium-containing precursor compounds in step a or step b are chosen from one or more compounds chosen from:

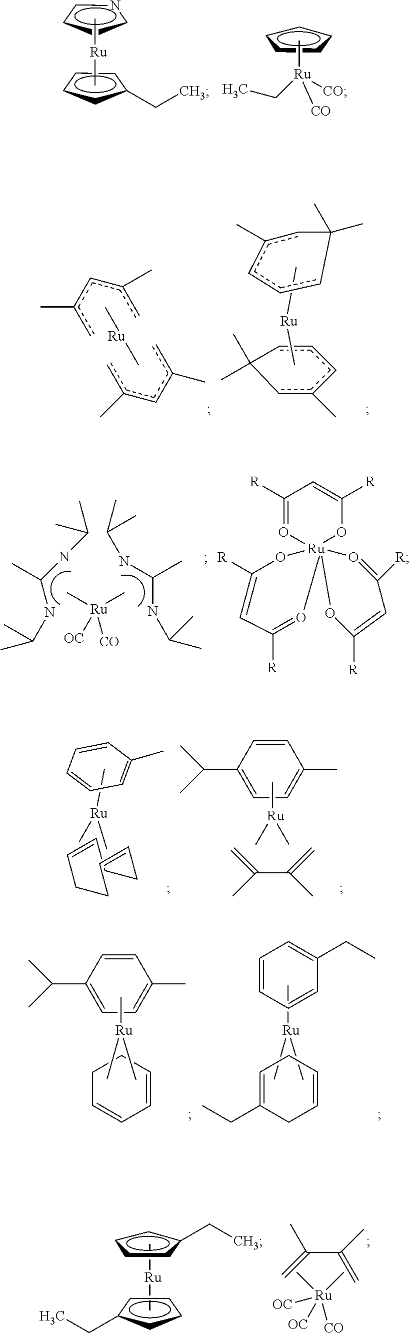

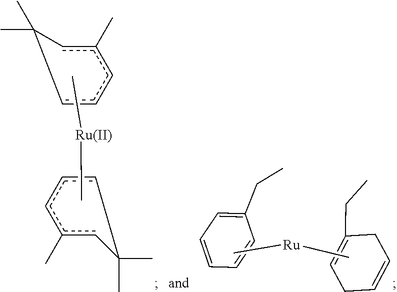

wherein R is chosen from C₁-C₄ alkyl.

In one embodiment, R is t-butyl.

The precursor composition comprising the compounds chosen from at least one of the above, can be employed for forming low resistivity ruthenium seed films onto various surfaces. In one embodiment, in step (a) above, the ruthenium seed layer is formed using a chemical vapor deposition technique.

In one embodiment, the tungsten, molybdenum, cobalt, ruthenium, or copper metal precursor as shown in step (b) is chosen from
a. Molybdenum precursors such as MoCl₅, MoOCl₄, and MoO₂Cl₂; Mo(CO)₆, MoH₂(ⁱPrCp)₂; (ⁱPr=isopropyl; Cp=cyclopentadienyl)
b. Tungsten precursors such as WF₆, and W(t-butyl-N)₂(N(CH₃)₂)₂; WCl₅ and WCl₆, WOCl₄; W(CO)₆, WH₂(ⁱPrCp)₂;
c. Cobalt precursors such as Co(t-Butyl-NCHCHN-t-Butyl)₂, Co₂(CO)₆(HCCCF₃), and Co₂(CO)₆(HCC(CH₃)₃). Additional cobalt precursors can be found in Alain E. Kaloyeros, et al., ECS Journal of Solid State Science and Technology, 8 (2) P119-P152 (2019) “Cobalt Thin Films: Trends in Processing Technologies and Emerging Applications”; and Seong Ho Han, et al., “New Heteroleptic Cobalt Precursors for Deposition of Cobalt-based Thin Films, ACS Omega, http://pubs.acs.org/journal/acsodf; and U.S. Pat. No. 10,872,770 and US Patent Publication 2018/044788, incorporated herein by reference; and
d. Copper precursors such as copper (I) amidinates and copper (I) guanidate precursors such as copper (I) 2-methoxy-1,3-diisopropylamidinate; copper (I) 2-ethoxy-1,3-diisopropylamidinate; copper (I) 2-t-butoxy-1,3-diisopropylamidinate; copper (I) 2-isopropyl-1,3-diisoproylamidinate; copper (I) 2-dimethylamino-1,3-diisopropylamidinate; (See, US Patent Publication No. 2005/0281952 and WO2007/1422700, incorporated herein by reference.) In one embodiment, the copper precursor is copper (I) N′, N″-diisopropyl-N, N-dimethyl guanidate, referred to below as “CuDMAPA”. See also Peter G. Gordon et al 2015 ECS J. Solid State Sci. Technol. 4N3188; and U.S. Pat. Nos. 7,964,746 and 7,858,525, and U.S. Patent Publication No. 2008/0281476, incorporated herein by reference.

The desired microelectronic device substrate may be placed in a reaction zone in any suitable manner, for example, in a single wafer CVD or ALD, or in a furnace containing multiple wafers.

In one alternative, the processes of the invention can be conducted as an ALD or ALD-like process. As used herein, the terms “ALD or ALD-like” refer to processes such as (i) each reactant including the precursor composition comprising the compounds set forth herein, the co-reactant(s) are introduced sequentially into a reactor such as a single wafer ALD reactor, semi-batch ALD reactor, or batch furnace ALD reactor, or (ii) each reactant is exposed to the substrate or microelectronic device surface by moving or rotating the substrate to different sections of the reactor and each section is separated by an inert gas curtain, i.e., spatial ALD reactor or roll to roll ALD reactor. In certain embodiments, the thickness of the resulting bulk ALD metal film may be from about 0.5 nm to about 40 nm.

The deposition methods disclosed herein may involve one or more purge gases. The purge gas, which is used to purge away unconsumed reactants and/or reaction by-products, is an inert gas that does not react with either the precursor composition or the counter-reactant(s). Exemplary purge gases include, but are not limited to, argon, nitrogen, helium, neon, and mixtures thereof. In certain embodiments, a purge gas such as Ar is supplied into the reactor at a flow rate ranging from about 10 to about 2000 sccm for about 0.1 to 1000 seconds, thereby purging the unreacted material and any by-product that may remain in the reactor. Such purge gases may also be utilized as inert carrier gases for either or both of the precursor composition and co-reactant(s).

Energy is applied to the precursor composition and the co-reactant(s) in the reaction zone to induce reaction and to form the film on the microelectronic device surface. Such energy can be provided by, but not limited to, thermal, pulsed thermal, plasma, pulsed plasma, helicon plasma, high density plasma, inductively coupled plasma, X-ray, e-beam, photon, remote plasma methods, and combinations thereof. In certain embodiments, a secondary RF frequency source can be used to modify the plasma characteristics at the substrate surface. In embodiments wherein the deposition involves plasma, the plasma-generated process may comprise a direct plasma-generated process in which plasma is directly generated in the reactor, or alternatively, a remote plasma-generated process in which plasma is generated ‘remotely’ of the reaction zone and substrate, being supplied into the reactor.

As used herein, the term “microelectronic device” corresponds to semiconductor substrates, including 3D NAND structures, flat panel displays, and microelectromechanical systems (MEMS), manufactured for use in microelectronic, integrated circuit, or computer chip applications. It is to be understood that the term “microelectronic device” is not meant to be limiting in any way and includes any substrate that includes a negative channel metal oxide semiconductor (nMOS) and/or a positive channel metal oxide semiconductor (pMOS) transistor and will eventually become a microelectronic device or microelectronic assembly.

Such microelectronic devices contain at least one substrate, which can be chosen from, for example, tin, SiO₂, Si₃N₄, OSG, FSG, tin carbide, hydrogenated tin carbide, tin nitride, hydrogenated tin nitride, tin carbonitride, hydrogenated tin carbonitride, boronitride, antireflective coatings, photoresists, germanium, germanium-containing, boron-containing, Ga/As, a flexible substrate, porous inorganic materials, metals such as copper and aluminum, and diffusion barrier layers such as but not limited to TiN, Ti(C)N, TaN, Ta(C)N, Ta, W, or WN.

### EXAMPLES

### Example 1—CVD Deposition of P-Cymene(1,3-Cyclohexadiene)Ru with H₂ Co-Reactant

Ru metal deposited at 300° C. and 30 Torr, using 4 μmole/min of p-Cymene CHD Ru and 0.4 1 pm (liters per minute) H₂.

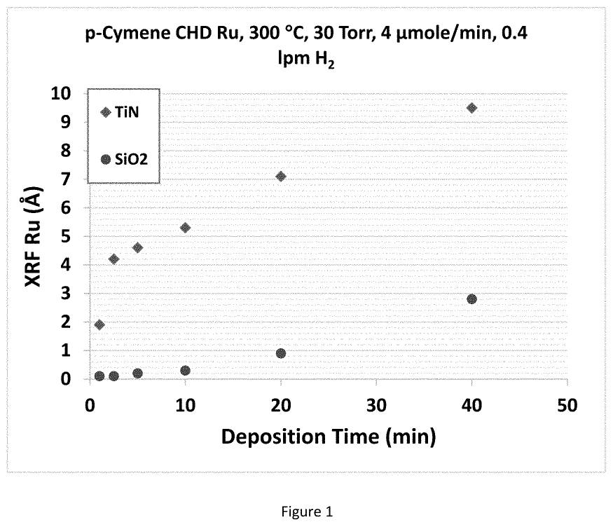

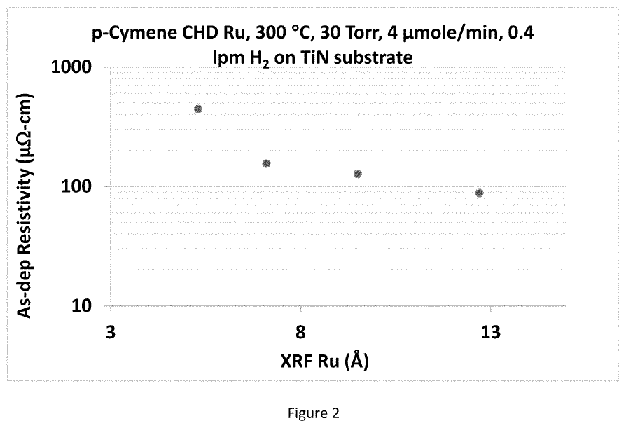

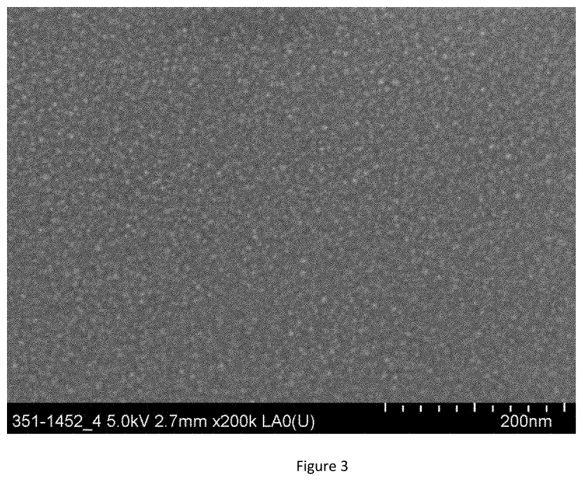

In this Example, ruthenium metal was deposited at 300° C. and 30 Torr. Data from this Example is set forth in FIG. 1, illustrating superior selectivity for deposition over titanium nitride versus silicon dioxide.

### Example 2—CVD Deposition of Ethylbenzyl(1-Ethyl-1,4 Cyclohexadienyl)Ru [Ebechd Ru] with H₂ Co-Reactant

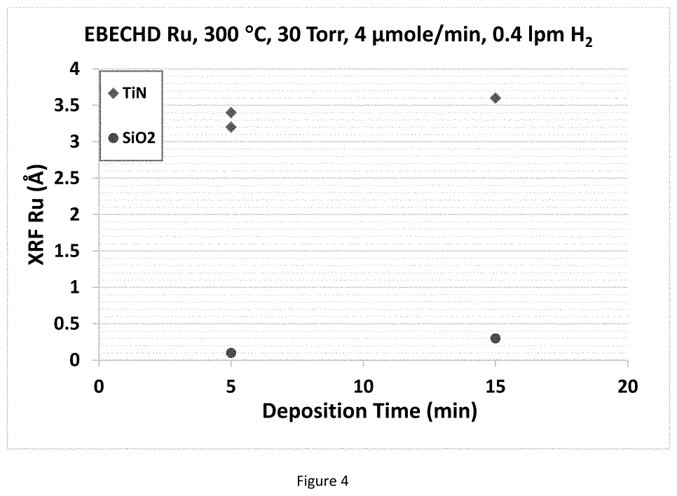

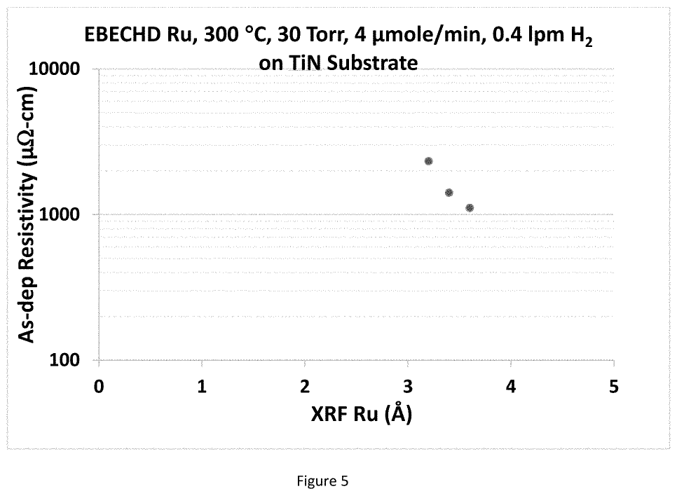

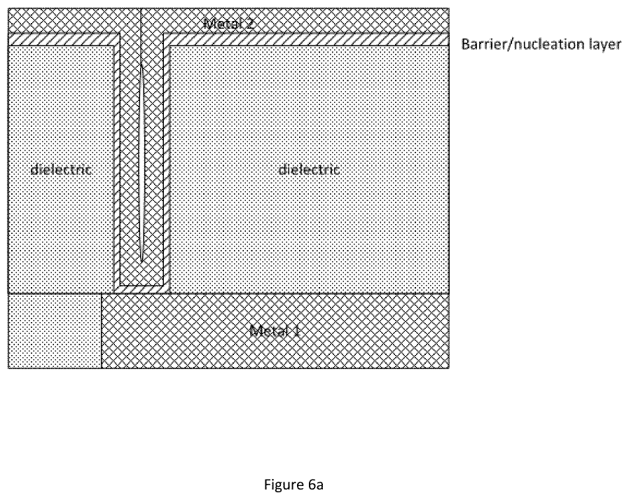

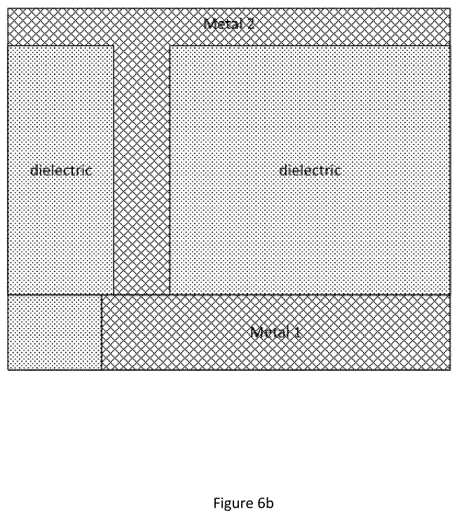

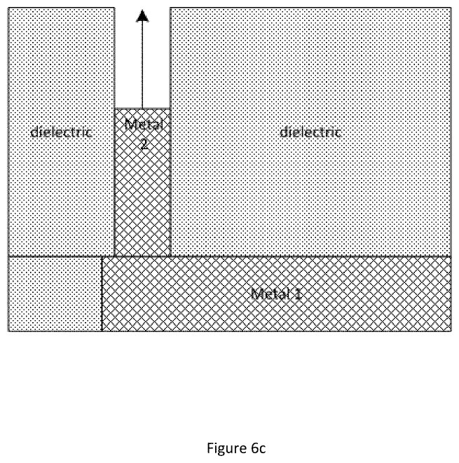

Using ethylbenzyl(1-ethyl-1,4-cyclohexadienyl)Ru (4 μmole/minute flow rate) as precursor, a ruthenium film was deposited at 300° C. and 30 Torr using and 0.4 l pm H₂ co-reactant. The data from this Example is set forth in FIG. 4, illustrating the self-limiting deposition and selectivity for titanium nitride over silicon dioxide.

### Example 3 (Second Step is Prophetic)

In a first step, 6 Å of Ru is deposited selectively onto TiN areas of the substrate under the conditions: 300° C. and 30 Torr, using 4 μmole/min of p-Cymene CHD Ru and 0.4 l pm (liters per minute) H₂ for a 3 minute deposition time. (Surrounding dielectric surfaces have <1 Å Ru.) In the second step, the substrate is held at 400° C. in 60 Torr of H₂ flowing at 2 slm (standard liters per minute). MoCl₅ vapor is delivered from a ProE-Vap ampoule held at 105° C. with Ar carrier gas at 300 sccm. 100 Å of Mo metal is deposited in about 10 minutes with a resistivity <30 μΩ-cm (microohm-cm).

### Example 4a (Ru Deposition)

In this example, 6 Å of Ru is deposited selectively onto TiN areas of the substrate under the conditions: 300° C. and 30 Torr, using 4 μmole/min of p-Cymene CHD Ru and 0.4 l pm (liters per minute) H₂ for a 3 minute deposition time. (Surrounding dielectric surfaces have <1 Å Ru.)

### Example 4b (Cu Deposition on a Sputtered Ru Surface)

In this example, 230 Å of Cu is deposited selectively onto the Ru layer under the following conditions: The substrate is held at 65° C. with the process pressure controlled at 1 Torr. There is a constant flow of 470 sccm of H₂ and 490 sccm of Ar. CuDMAPA vapor is delivered from a ProE-Vap ampoule held at 95° C. with Ar carrier gas at 95 Torr upstream of the ampoule in pulses 18 s long. The Cu precursor flow is stopped for 0.5 s of purge time. A direct plasma of 150 W is lit for 1.5 s followed by 0.05 s of purge after the plasma. After 550 cycles, the film is 230 Å thick with a resistivity of 5.1μΩ-cm (microohm-cm).

### Example 5a (Ru Deposition)

In this example, 6 Å of Ru is deposited selectively onto TiN areas of the substrate under the conditions: 300° C. and 30 Torr, using 4 μmole/min of p-Cymene CHD Ru and 0.4 l pm (liters per minute) H₂ for a 3 minute deposition time. (Surrounding dielectric surfaces have <1 Å Ru.)

### Example 5b (Co Deposition on a Sputtered Ru Surface)

In this example, the substrate is held at 200° C. in 30 Torr of H₂ flowing at 0.5 slm. Ten (10) micromole per minute of Co(t-butyl-NCHCHN-t-butyl)₂ vapor is delivered from a vaporizer held at 130° C. with He carrier gas at 100 sccm. 300 Å of Co metal is deposited selectively in about 15 minutes with a resistivity˜12 μΩ-cm (microohm-cm).

Aspects

In a first aspect, the invention provides a process for depositing a metal-containing film onto a microelectronic device substrate, wherein the metal is chosen from tungsten, molybdenum, cobalt, ruthenium, and copper, and wherein the substrate is chosen from titanium nitride, tungsten nitride, tantalum nitride, niobium nitride, tungsten, molybdenum, cobalt, and copper, which comprises:
a. introducing an oxygen-free ruthenium precursor material into a reaction zone containing the substrate, in the presence of a reducing gas, under vapor deposition conditions, until the ruthenium-containing film is about 3 to about 15 Å in thickness, followed by
b. introducing a tungsten, molybdenum, cobalt, ruthenium, or copper metal-containing precursor into the reaction zone, under vapor deposition conditions, until a tungsten, molybdenum, cobalt, ruthenium, or copper metal-containing film of a desired thickness has been obtained.

In a second aspect, the invention provides the process of the first aspect, wherein the ruthenium precursor material in (a) is introduced into a reaction zone under chemical vapor deposition conditions.

In a third aspect, the invention provides the process of the first aspect, wherein the tungsten, molybdenum, cobalt, ruthenium, or copper metal-containing precursor is introduced into the reaction zone under chemical vapor deposition conditions.

In a fourth aspect, the invention provides the process of the first aspect, wherein the tungsten, molybdenum, cobalt, ruthenium, or copper metal-containing precursor is introduced into the reaction zone under atomic layer deposition or pulsed CVD conditions.

In a fifth aspect, the invention provides the process of any one of the first through the fourth aspects, wherein tungsten, molybdenum, cobalt, ruthenium, or copper metal-containing precursor is chosen from
MoCl₅, MoOCl₄, MoO₂Cl₂; Mo(CO)₆, MoH₂(ⁱPrCp)₂;
WF₆, W(t-butyl-N)₂(N(CH₃)₂)₂, WCl₅, WCl₆, and WOCl₄; W(CO)₆, WH₂(ⁱPrCp)₂;
Co(t-Butyl-NCHCHN-t-Butyl)₂, Co₂(CO)₆(HCCCF₃), and Co₂(CO)₆(HCC(CH₃)₃);
Copper (I) 2-methoxy-1,3-diisopropylamidinate; copper (I) 2-ethoxy-1,3-diisopropylamidinate; copper (I) 2-t-butoxy-1,3-diisopropylamidinate; copper (I) 2-isopropyl-1,3-diisoproylamidinate; and copper (I) 2-dimethylamino-1,3-diisopropylamidinate.

In a sixth aspect, the invention provides the process of any one of the first through the fifth aspects, wherein the molybdenum metal-containing precursor is chosen from MoCl₅, MoOCl₄, or MoO₂Cl₂.

In a seventh aspect, the invention provides the process of any one of the first through the fourth aspects, wherein the tungsten metal-containing precursor is chosen from WF₆ and W(t-butyl-N)₂(N(CH₃)₂)₂.

In an eighth aspect, the invention provides the process of any one of the first through the fourth aspects, wherein the copper metal-containing precursor is copper (I) N′, N″-diisopropyl-N, N-dimethyl guanidate.

In a ninth aspect, the invention provides the process of any one of the first through the fourth aspects, wherein the ruthenium metal-containing precursor comprises one or more compounds chosen from:

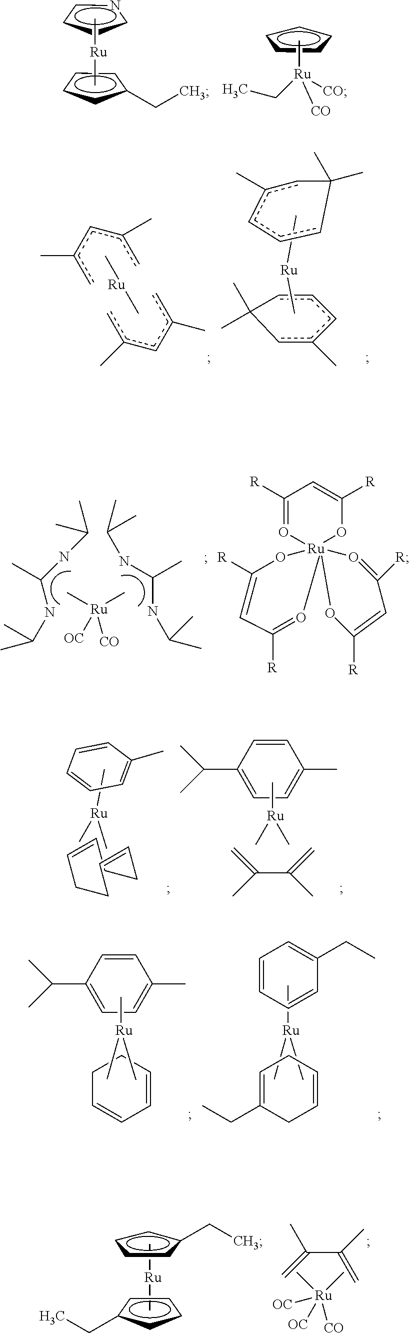

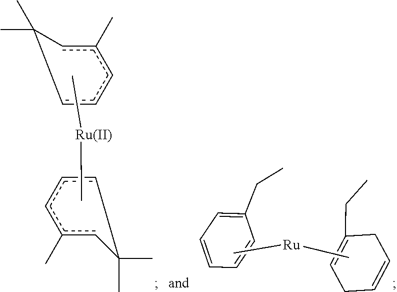

wherein R is chosen from C₁-C₄ alkyl.

In a tenth aspect, the invention provides the process of the ninth aspect, wherein R is t-butyl.

In an eleventh aspect, the invention provides the process any one of the first through the tenth aspects, wherein the oxygen-free ruthenium precursor comprises a compound chosen from the formulae:

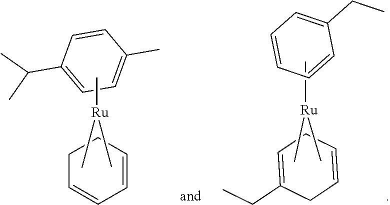

In a twelfth aspect, the invention provides the process of any one of the first through the fourth, or ninth aspects, wherein the ruthenium metal-containing precursor comprises a compound chosen from:

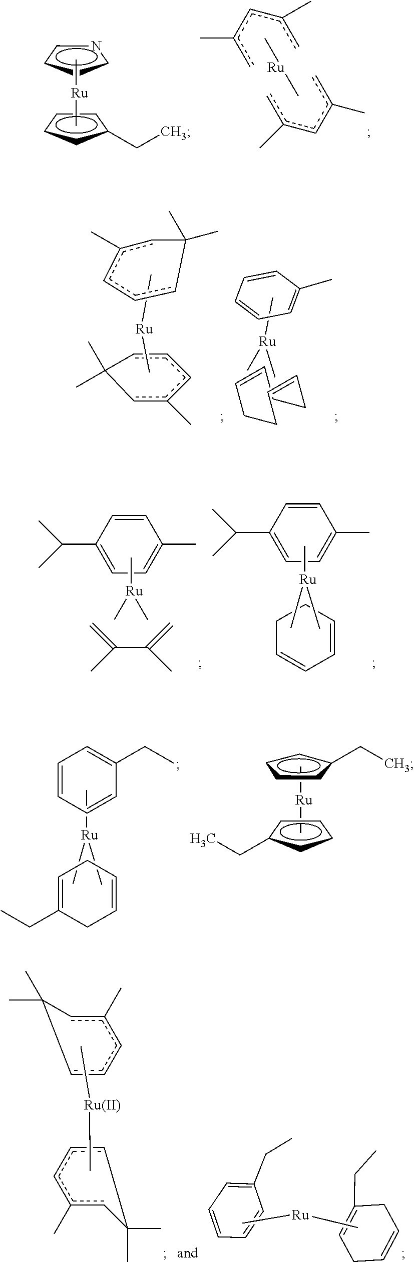

wherein R is chosen from C₁-C₄ alkyl.

In a thirteenth aspect, the invention provides the process any one of the first through fourth, or ninth aspects, wherein the ruthenium metal-containing precursor comprises one or more compounds chosen from:

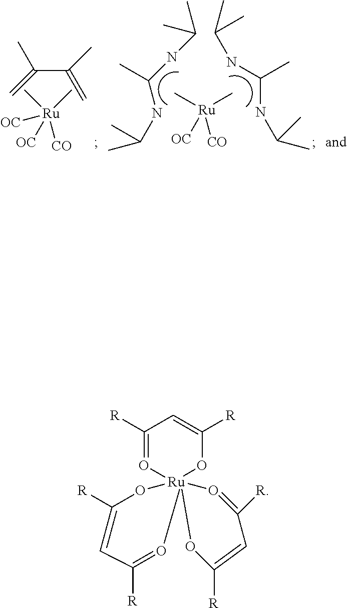

In a fourteenth aspect, the invention provides the process of any one of the first through twelfth aspects, wherein the ruthenium-containing film of step a. exhibits an electrical resistivity of about 450 μΩ-cm for a film having a thickness of about 5.3 Å.

Having thus described several illustrative embodiments of the present disclosure, those of skill in the art will readily appreciate that yet other embodiments may be made and used within the scope of the claims hereto attached. Numerous advantages of the disclosure covered by this document have been set forth in the foregoing description. It will be understood, however, that this disclosure is, in many respects, only illustrative. The disclosure's scope is, of course, defined in the language in which the appended claims are expressed.

What is claimed is:

1. A process for depositing a metal-containing film onto a microelectronic device substrate, wherein the metal is chosen from tungsten, molybdenum, cobalt, ruthenium, and copper, and wherein the substrate is chosen from titanium nitride, tungsten nitride, tantalum nitride, niobium nitride, tungsten, molybdenum, cobalt, and copper, which comprises:
a. introducing an oxygen-free ruthenium precursor material into a reaction zone containing the substrate, in the presence of a reducing gas, under vapor deposition conditions, until the ruthenium-containing film is about 3 to about 15 Å in thickness, followed by
b. introducing a tungsten, molybdenum, cobalt, ruthenium, or copper metal-containing precursor into the reaction zone, under vapor deposition conditions, until a tungsten, molybdenum, cobalt, ruthenium, or copper metal-containing film of a desired thickness has been obtained.

2. The process of claim 1, wherein the ruthenium precursor material in (a) is introduced into a reaction zone under chemical vapor deposition conditions.

3. The process of claim 1, wherein the tungsten, molybdenum, cobalt, ruthenium, or copper metal-containing precursor is introduced into the reaction zone under chemical vapor deposition conditions.

4. The process of claim 1, wherein the tungsten, molybdenum, cobalt, ruthenium, or copper metal-containing precursor is introduced into the reaction zone under atomic layer deposition or pulsed CVD conditions.

5. The process of claim 1, wherein tungsten, molybdenum, cobalt, ruthenium, or copper metal-containing precursor is chosen from
a. MoCl₅, MoOCl₄, MoO₂Cl₂; Mo(CO)₆, MoH₂(ⁱPrCp)₂;
b. WF₆, W(t-butyl-N)₂(N(CH₃)₂)₂, WCl₅, WCl₆, and WOCl₄; W(CO)₆, WH₂(ⁱPrCp)₂;
c. Co(t-Butyl-NCHCHN-t-Butyl)₂, Co₂(CO)₆(HCCCF₃), and Co₂(CO)₆(HCC(CH₃)₃); and
d. Copper (I) 2-methoxy-1,3-diisopropylamidinate; copper (I) 2-ethoxy-1,3-diisopropylamidinate; copper (I) 2-t-butoxy-1,3-diisopropylamidinate; copper (I) 2-isopropyl-1,3-diisoproylamidinate; and copper (I) 2-dimethylamino-1,3-diisopropylamidinate.

6. The process of claim 1, wherein the molybdenum metal-containing precursor is chosen from MoCl₅, MoOCl₄, or MoO₂Cl₂.

7. The process of claim 1, wherein the tungsten metal-containing precursor is chosen from WF₆ and W(t-butyl-N)₂(N(CH₃)₂)₂.

8. The process of claim 1, wherein the copper metal-containing precursor is copper (I) N′, N″-diisopropyl-N, N-dimethyl guanidate.

9. The process of claim 1, wherein the ruthenium metal-containing precursor comprises one or more compounds chosen from: 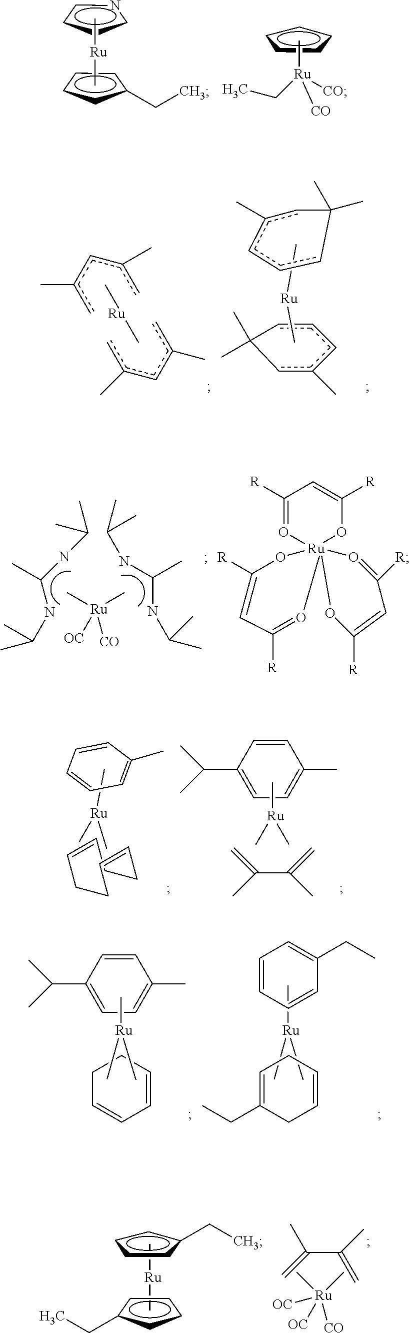 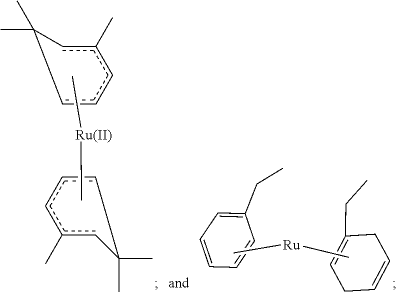
wherein R is chosen from C₁-C₄ alkyl.

10. The process of claim 9, wherein R is t-butyl.

11. The process of claim 1, wherein the oxygen-free ruthenium precursor comprises a compound chosen from the formulae:

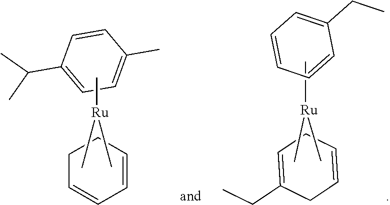

12. The process of claim 1, wherein the ruthenium metal-containing precursor comprises a compound chosen from: 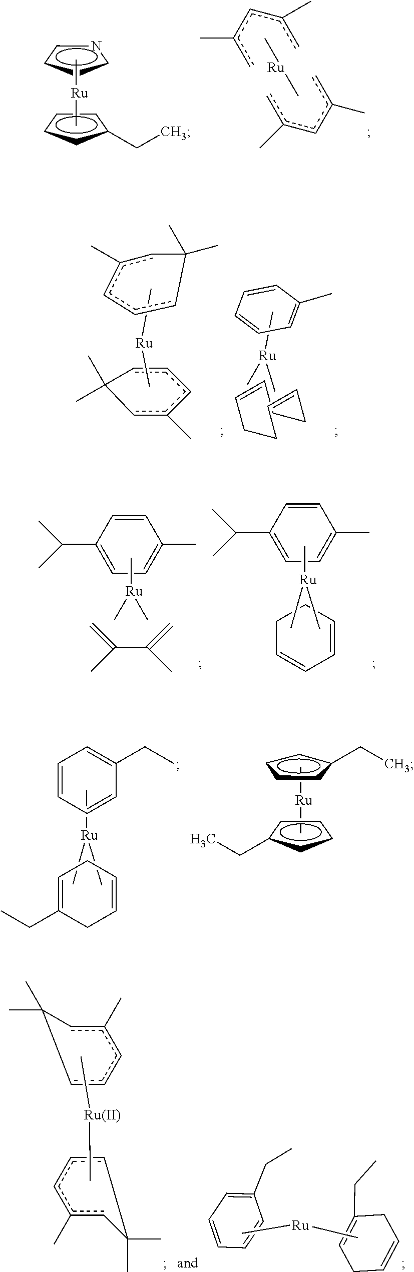
wherein R is chosen from C₁-C₄ alkyl.

13. The process of claim 7, wherein the ruthenium metal-containing precursor comprises one or more compounds chosen from:

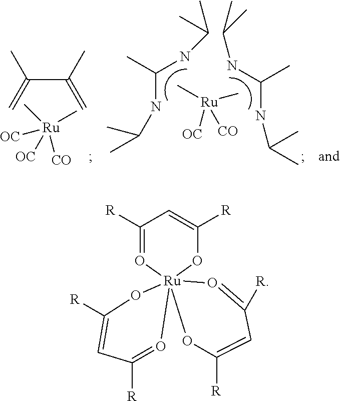

14. The process of claim 1, wherein the ruthenium-containing film of step a. exhibits an electrical resistivity of about 450 μΩ-cm for a film having a thickness of about 5.3 Å.
